(19) United States
(12) Patent Application Publication
(10) Pub. No.: US 2026/0205076 A1
(43) Pub. Date: Jul. 16, 2026

(54) RF AMPLIFIER

(71) Applicant: STMicroelectronics International N.V., Geneva (CH)

(72) Inventors: Vincent KNOPIK, Crets en Belledonne (FR); Jeremie FOREST, Le Cheylas (FR)

(73) Assignee: STMicroelectronics International N.V., Geneva (CH)

(21) Appl. No.: 19/436,633

(22) Filed: Dec. 30, 2025

(30) Foreign Application Priority Data
Jan. 13, 2025 (FR) FR2500336

(51) Int. Cl. H03F 3/45

(52) U.S. Cl. CPC H03F 3/45085; H03F 3/45183; H03F 2200/451; H03F 2203/45034; H03F 2203/45316

(57) ABSTRACT

A radio frequency signal amplifier includes an input differential transistor pair and an output differential transistor pair. First and second capacitive elements are arranged, respectively, between control terminals and conduction terminals of transistors of the input differential transistor pair. Third and fourth capacitive elements are arranged, respectively, between control terminals and conduction terminals of transistors of the output differential transistor pair. These capacitive elements may be formed by transistors or capacitors. An amplifier input is coupled through a transformer to the control terminals of the transistors of the input differential transistor pair. An amplifier output is coupled to through magnetically coupled coils to further conduction terminals of the transistors of the output differential transistor pair.

### PRIORITY CLAIM

This application claims the priority benefit of French Application for Patent No. FR2500336 filed on January 13, 2025, the content of which is hereby incorporated by reference in its entirety to the maximum extent allowable by law.

### TECHNICAL FIELD

The present disclosure generally to electronic systems and devices and, more particularly, to the processing of signals by these electronic systems and devices. The present disclosure more specifically concerns the improvement of a radio frequency signal amplifier.

### BACKGROUND

Amplifiers are electronic devices used to amplify the amplitude of one or more electronic signals, and for example signals used in the radio frequency field, that is, signals having frequencies in the range from a few hertz to more than 300 kHz, for example in the range from 3 kHz to 300 GHz.

It would be desirable to be able to improve, at least partly, certain aspects of signal amplifiers, and in particular of radio frequency signal amplifiers.

There exists a need for higher-performance signal amplifiers, exhibiting less signal loss.

There exists a need for higher-performance radio frequency signal amplifiers, exhibiting less signal loss.

There is a need to overcome all or part of the disadvantages of known radio frequency signal amplifiers.

There is a need to overcome all or part of the disadvantages of known amplifiers by compensating for internal capacitances of transistors of differential pairs forming it.

### SUMMARY

An embodiment provides a radio frequency signal amplifier comprising: a first input differential pair including a first transistor and a second transistor; a second output differential pair including a third transistor and a fourth transistor; a first capacitive element arranged between a control terminal of said first transistor and a conduction terminal of said second transistor; a second capacitive element arranged between a control terminal of said second transistor and a conduction terminal of said first transistor; a third capacitive element arranged between a control terminal of said third transistor and a conduction terminal of said fourth transistor; and a fourth capacitive element arranged between a control terminal of said fourth transistor and a conduction terminal of said third transistor.

Another embodiment provides a method of amplification of radio frequency signals using a radio frequency signal amplifier comprising: a first input differential pair comprising a first transistor and a second transistor; a second output differential pair comprising a third transistor and a fourth transistor; a first capacitive element arranged between a control terminal of said first transistor and a conduction terminal of said second transistor; a second capacitive element arranged between a control terminal of said second transistor and a conduction terminal of said first transistor; a third capacitive element arranged between a control terminal of said third transistor and a conduction terminal of said fourth transistor; and a fourth capacitive element arranged between a control terminal of said fourth transistor and a conduction terminal of said third transistor.

According to an embodiment, said first capacitive element is a transistor or a capacitor.

According to an embodiment, said second capacitive element is a transistor or a capacitor.

According to an embodiment, said third capacitive element is a transistor or a capacitor.

According to an embodiment, said fourth capacitive element is a transistor or a capacitor.

According to an embodiment, said amplifier comprises at least one coil arranged between the first and second differential pairs.

According to an embodiment, when at least one of said first, second, third, and fourth capacitive elements is a transistor, then its control terminal is coupled to one of its conduction terminals.

According to an embodiment, when at least one of said first, second, third, and fourth capacitive elements is a transistor, then this transistor is of a same technology as the transistor having its control terminal coupled to this transistor.

According to an embodiment, when at least one of said first, second, third, and fourth capacitive elements is a transistor, then this transistor has same dimensions as the transistor having its control terminal coupled to this transistor.

According to an embodiment, the first, second, third, or fourth transistors are bipolar transistors.

According to an embodiment, the first, second, third, or fourth transistors are MOSFET-type transistors.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows an electrical diagram of a first embodiment of a radio frequency signal amplifier;

FIG. 2 shows an electrical diagram of a second embodiment of a radio frequency signal amplifier;

FIG. 3 shows two graphs (A) and (B) illustrating an advantage of the embodiments described in relation with FIGS. 1 and 2;

FIG. 4 shows two graphs (C) and (D) illustrating another advantage of the embodiments described in relation with FIGS. 1 and 2; and

FIG. 5 shows two graphs (E) and (F) illustrating another advantage of the embodiments described in relation with FIGS. 1 and 2.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only those steps and elements that are useful for understanding the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected, or they can be coupled via one or more other elements.

In the following description, where reference is made to absolute position qualifiers, such as the terms "front", "back", "top", "bottom", "left", "right", etc., or relative position qualifiers, such as the terms "top", "bottom", "upper", "lower", etc., or orientation qualifiers, such as "horizontal", "vertical", etc., reference is made unless otherwise specified to the orientation of the drawings.

Unless specified otherwise, the expressions "about", "approximately", "substantially", and "in the order of" signify plus or minus 10%, preferably of plus or minus 5%.

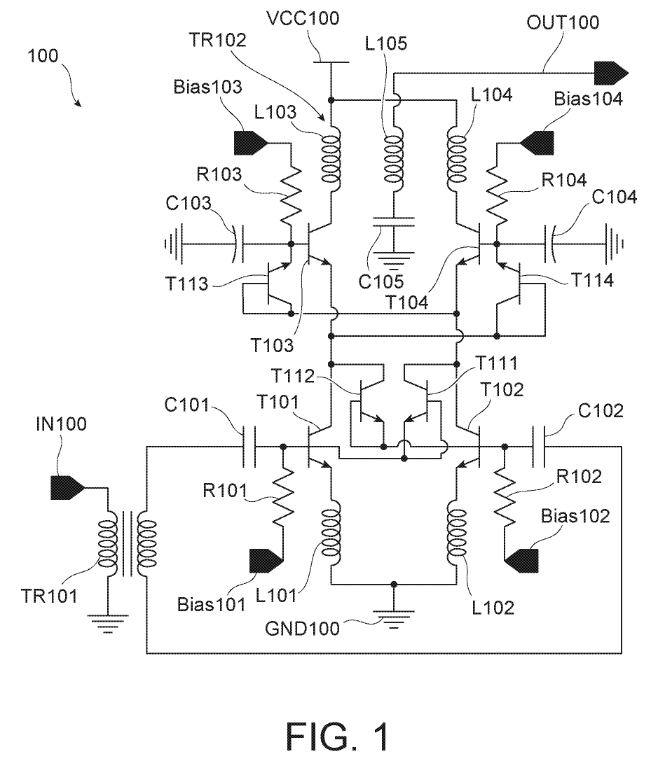

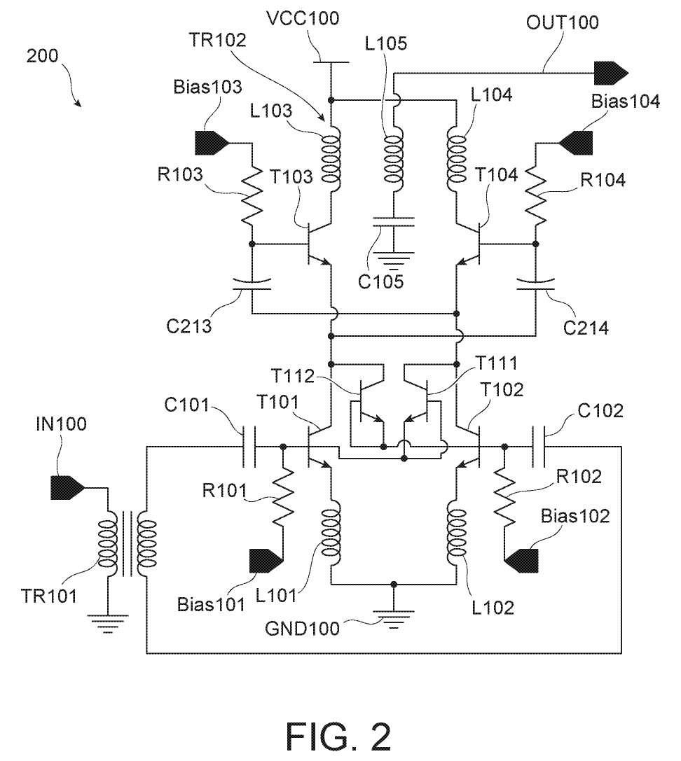

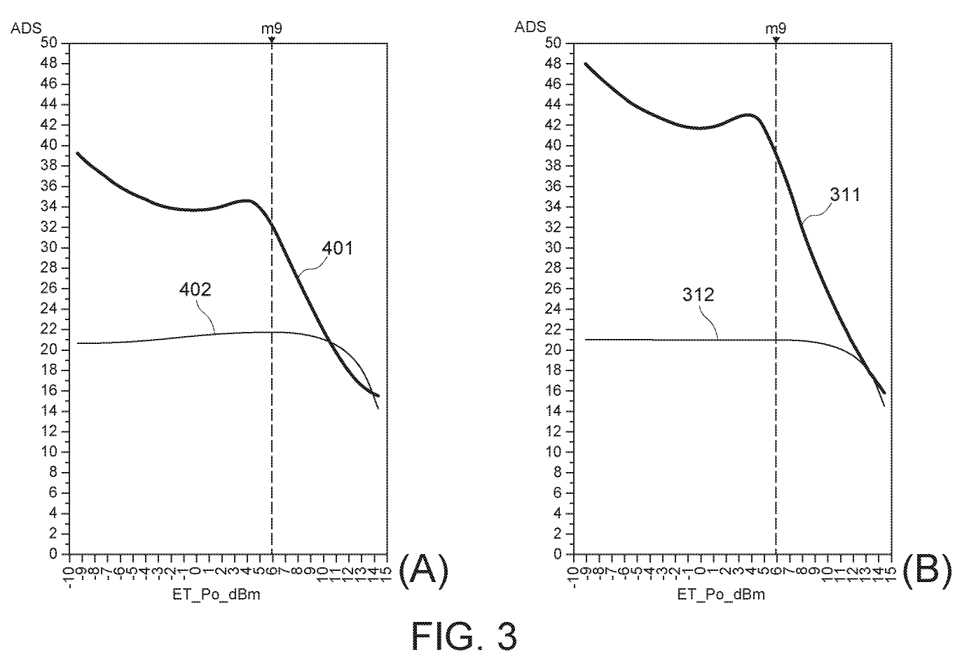

The embodiments described hereafter concern signal amplification and, in particular, a signal amplifier exhibiting less signal loss. These embodiments apply, in particular, to amplifiers for radio frequency signals, that is, signals having frequencies in the range from a few hertz to more than 300 kHz, for example in the range from 3 kHz to 300 GHz. These embodiments comprise capacitive elements configured to compensate for internal capacitances of transistors of differential pairs forming the amplifier. Two types of capacitive elements may be used and are described in relation with FIGS. 1 and 2. The advantages of these embodiments are detailed in relation with FIGS. 3 to 5.

Further, the described embodiments are particularly configured for use in any type of industrial market where radio frequency signals are used. More particularly, such a radio frequency signal amplifier may be intended for: the automotive industry, for example in the field of automotive electrification or in the field of advanced driver assistance systems (ADAS); the industrial sector, for example in the field of green energy, in the field of infrastructure electrification, of the Internet of Things (IoT) and of smart homes, where electricity and energy consumption and data exchange are key elements; the personal electronics industry, for example in the field of mobile telephony and of the Internet of Things (IoT), as well as in high speed interfaces; and the industry of communications equipment, computers, and peripherals, for example in the field of infrastructure and data centers, and in the field of low earth orbit (LEO) satellites.

FIG. 1 is an electrical diagram of an embodiment of a signal amplifier circuit 100 and, more particularly, a radio frequency signal amplifier circuit 100, or radio frequency signal amplifier 100.

Amplifier 100 comprises an input terminal IN100 configured to receive an input signal, and an output terminal OUT100 configured to deliver an output signal. This output signal is equal to the amplified input signal.

According to an example, amplifier 100 comprises, as an input, a transformer TR101 formed by two coils coupled to each other. According to an example, a first terminal of a first coil of transformer TR101 is coupled, preferably connected, to input terminal IN100, and a second terminal of this coil is coupled, preferably connected, to a node receiving a reference potential GND100, for example the ground. According to an example, a second coil of transformer TR101 delivers the input signal to the rest of the components of amplifier 100.

According to an embodiment, amplifier 100 further comprises a first, or input, differential pair comprising two transistors T101 and T102. According to a preferred example, transistors T101 and T102 are of same technology (for example, both bipolar or both MOSFET) and of same dimensions. According to another example, transistors T101 and T102 may be of different technology and/or dimensions. According to a first example illustrated in FIG. 1, transistors T101 and T102 are transistors in bipolar technology, and more particularly NPN-type bipolar transistors. According to a second example, transistors T101 and T102 are metal-oxide-semiconductor field-effect transistors, or MOSFET transistors, or MOS transistors. Other transistor technologies can be envisaged by those skilled in the art to form the input differential pair

According to an example, a control terminal of transistor T101 is coupled to a first terminal of the second coil of transformer TR101, for example, via a capacitor C101. According to an example, a first conduction terminal of transistor T101 is coupled to the node receiving reference potential GND100, for example, via a coil L101.

According to an example, a control terminal of transistor T102 is coupled to a second terminal of the second coil of transformer TR101, for example, via a capacitor C102. According to an example, a first conduction terminal of transistor T102 is coupled to the node receiving reference potential GND100, for example, via a coil L102.

According to an example, amplifier 100 further comprises two bias resistors R101 and R102. According to an example, a first terminal of resistor R101 is coupled, preferably connected, to the control terminal of transistor T101, and a second terminal of resistor R101 is configured to receive a bias potential Bias101. According to an example, a first terminal of resistor R102 is coupled, preferably connected, to the control terminal of transistor T102, and a second terminal of resistor R102 is configured to receive a bias potential Bias102. According to a preferred example, resistors R101 and R102 are identical and bias potentials Bias101 and Bias102 are equal.

According to an embodiment, amplifier 100 further comprises a second, or output, differential pair comprising two transistors, T103 and T104. According to a preferred example, transistors T103 and T104 are of same technology and of same dimensions. According to another example, transistors T103 and T104 may be of different technology and/or dimensions. According to a first example illustrated in FIG. 1, transistors T103 and T104 are transistors in bipolar technology, and more particularly NPN-type bipolar transistors. According to a second example, transistors T103 and T104 are MOS transistors. Other transistor technologies may be envisaged by those skilled in the art to form the output differential pair.

According to an example, a first conduction terminal of transistor T103 is coupled, preferably connected, to a second conduction terminal of transistor T101. A control terminal of transistor T103 is configured to receive a bias potential Bias103, for example, via a resistor R103. According to an example, the conduction terminal of transistor T103 may, further, be coupled to the node receiving reference potential GND100 via a filtering capacitor C103.

According to an example, a first conduction terminal of transistor T104 is coupled, preferably connected, to a second conduction terminal of transistor T102. A control terminal of transistor T104 is configured to receive a bias potential Bias104, for example, via a resistor R104. According to an example, the conduction terminal of transistor T104 may, further, be coupled to the node receiving reference potential GND100 via a filtering capacitor C104.

According to a preferred example, resistors R103 and R104 are identical and bias potentials Bias103 and Bias104 are also equal.

According to an example, amplifier 100 further comprises an output transformer TR102 formed by three coils L103, L104 and L105 magnetically coupled to one another. According to an example, a first terminal of coil L103 is coupled, preferably connected, to a node configured to receive a power supply potential VCC100, and a second terminal of coil L103 is coupled, preferably connected, to a second conduction terminal of transistor T103. According to an example, a first terminal of coil L104 is coupled, preferably connected, to the node configured to receive power supply potential VCC100, and a second terminal of coil L104 is coupled, preferably connected, to a second conduction terminal of transistor T104. A first terminal of coil L105 is coupled, preferably connected, to the output terminal OUT100 of amplifier 100, and a second terminal of coil L105 is coupled to the node receiving reference potential GND100, for example, via a capacitor C105.

According to an embodiment, each transistor of the input and output differential pairs is associated with a capacitive element enabling, among other things, to compensate for its parasitic capacitance formed between its control terminal and one of its conduction terminals. For this purpose, and still according to an embodiment, amplifier 100 comprises four capacitive elements formed, in FIG. 1, by transistors T111, T112, T113, and T114. Other options for forming the capacitive elements are described in relation with FIG. 2.

According to an embodiment, transistor T111 is configured to compensate for the parasitic capacitance of transistor T101. According to an example, a first conduction terminal of transistor T111 is coupled, preferably connected, to its control terminal and to the control terminal of transistor T101. According to an example, a second conduction terminal of transistor T111 is coupled, preferably connected, to the second conduction terminal of transistor T102. According to a preferred example, transistor T111 is of same technology and of same dimensions as transistor T101.

According to an embodiment, transistor T112 is configured to compensate for the parasitic capacitance of transistor T102. According to an example, a first conduction terminal of transistor T112 is coupled, preferably connected, to its control terminal and to the control terminal of transistor T102. According to an example, a second conduction terminal of transistor T112 is coupled, preferably connected, to the second conduction terminal of transistor T101. According to a preferred example, transistor T112 is of same technology and of same dimensions as transistor T102.

According to an embodiment, transistor T113 is configured to compensate for the parasitic capacitance of transistor T103. According to an example, a first conduction terminal of transistor T113 is coupled, preferably connected, to its control terminal and to the control terminal of transistor T103. According to an example, a second conduction terminal of transistor T113 is coupled, preferably connected, to the second conduction terminal of transistor T104. According to a preferred example, transistor T113 is of same technology and of same dimensions as transistor T103.

According to an embodiment, transistor T114 is configured to compensate for the parasitic capacitance of transistor T104. According to an example, a first conduction terminal of transistor T114 is coupled, preferably connected, to its control terminal and to the control terminal of transistor T104. According to an example, a second conduction terminal of transistor T114 is coupled, preferably connected, to the second conduction terminal of transistor T103. According to a preferred example, transistor T114 is of same technology and of same dimensions as transistor T104.

A radio frequency signal amplification method is a method of use of amplifier 100.

The advantages of the use of an amplifier 100 are described in relation with FIGS. 3 to 5.

FIG. 2 is an electrical diagram of another embodiment of a signal amplifier circuit 200, and more specifically of a radio frequency signal amplifier circuit 200, or radio frequency signal amplifier 200.

Amplifier 200 is similar to the amplifier 100 described in relation with FIG. 1. The elements common to amplifiers 100 and 200 are not described again in detail. Only the differences between amplifiers 100 and 200 are highlighted.

More particularly, in amplifier 200, some of the capacitive elements are not formed by transistors but by capacitors. Like amplifier 100, amplifier 100 comprises: an input terminal IN100; an output terminal OUT100; an optional input transformer TR101, formed by two coils; an optional output transformer TR102, formed by three coils L103, L104, and L105; an input differential pair comprising two transistors T101 and T102; an output differential pair comprising two transistors T103 and T104; two optional coils L101 and L102; two optional resistors R01 and R102; two optional filtering capacitors C101 and C102; and two optional resistors R103 and R104.

Further, amplifier 200 is configured to receive, like amplifier 100, a reference potential GND100, a power supply potential VCC100, and bias potentials Bias101, Bias102, Bias103, and Bias104.

Like amplifier 100, amplifier 200 comprises capacitive elements arranged so as to compensate for the internal capacitances of the transistors of the input and output differential pairs. In FIG. 2, these capacitive elements are formed by transistors T111 and T112 as in FIG. 1, but also by capacitors C213 and C214. In other words, each of the transistors T111, T112, T113, and T114 described in relation with FIG. 1 may be replaced by a capacitor, but this only concerns transistors T113 and T114 in FIG. 2.

According to an example, a first terminal of capacitor C213 is coupled, preferably connected, to the control terminal of transistor T103, and a second terminal of capacitor C213 is coupled, preferably connected, to the second conduction terminal of transistor T114. According to an example, a first terminal of capacitor C214 is coupled, preferably connected, to the control terminal of transistor T104, and a second terminal of capacitor C214 is coupled, preferably connected, to the second conduction terminal of transistor T113.

Further, amplifier 200 may further comprise coils (not shown in FIG. 2) arranged between the input differential pair and the output differential pair. More particularly, a first coil may be arranged between the second conduction terminal of transistor T101 and the first conduction terminal of transistor T103. A second coil may be arranged between the second conduction terminal of transistor T102 and the first conduction terminal of transistor T104.

A method of amplification of a radio frequency signal is a method of use of amplifier 200.

The advantages of the use of an amplifier 200 are described in relation with FIGS. 3 to 5.

FIG. 3 comprises two graphs (A) and (B) illustrating the performance of signal amplifiers, and more specifically, of radio frequency signal amplifiers.

Graph (A) more specifically illustrates the performance of a radio frequency signal amplifier of the type of the amplifiers 100 and 200 described in relation with FIGS. 1 and 2 but not comprising capacitive elements of the type of transistors T111, T112, T113, and T114 or of the type of capacitors C213 and C214. Graph (B) more specifically illustrates the performance of a radio frequency signal amplifier of the type of amplifiers 100 and 200 which use capacitive elements of the type of transistors T111, T112, T113, and T114 or of the type of capacitors C213 and C214. The comparison of graphs (A) and (B) enables to study the differences introduced by the use of these capacitive elements.

Further, graph (A) comprises: a linearity curve 301 illustrating the variation of the linearity of the output signal versus the output power of the output signal; and a gain curve 302 illustrating the variation of amplitude of the output signal versus the gain.

Further, graph (B) comprises: a linearity curve 311 illustrating the variation of the linearity of the output signal versus the output power of the output signal; and a gain curve 312 illustrating the variation of the amplitude of the output signal versus the gain.

There clearly appears from the study of these graphs that the linearity is improved, that is, has a higher value, for a given power value. It is also possible to state that for an identical power and a similar gain, the linearity curve is higher and thus more linear.

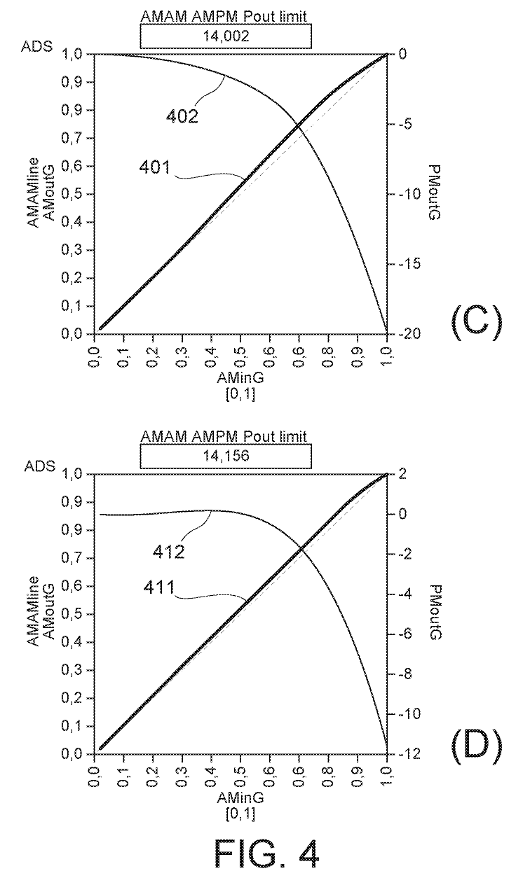

FIG. 4 comprises two graphs (C) and (D) illustrating the performance of signal amplifiers and, more particularly, of radio frequency signal amplifiers.

Graph (C) more specifically illustrates the performance of a radio frequency signal amplifier of the type of the amplifiers 100 and 200 described in relation with FIGS. 1 and 2 but comprising no capacitive elements of the type of transistors T111, T112, T113, and T114 or of the type of capacitors C213 and C214. Graph (D) more specifically illustrates the performance of a radio frequency signal amplifier of the type of amplifiers 100 and 200 which utilize capacitive elements of the type of transistors T111, T112, T113, and T114 or of the type of capacitors C213 and C214. The comparison of graphs (C) and (D) enables to study the differences introduced by the use of these capacitive elements.

Further, graph (C) comprises: a curve 401 illustrating the amplitude distortion for a given power of the output signal, here equal to 14 dBm, also called AM (Amplitude Magnitude) or amplitude modulus curve; and a curve 402 of phase distortion for a given output signal power, here equal to 14 dBm, also known as the PM (Phase Magnitude) or phase modulus curve.

Further, graph (D) comprises: a curve 411 illustrating the amplitude distortion for a given power of the output signal, here equal to 14 dBm; and a curve 412 of phase distortion for a given power of the output signal, here equal to 14 dBm.

The gain variation curve is more linear due to the use of capacitive elements, and the phase distortion is also more attenuated, that is, lower.

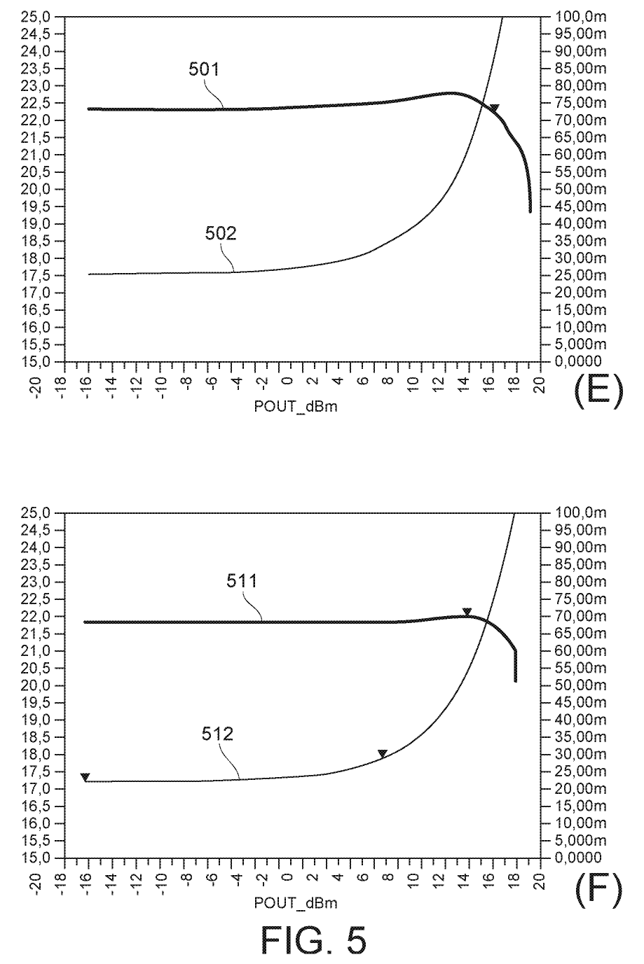

FIG. 5 comprises two graphs (E) and (F) illustrating the performance of signal amplifiers, and more particularly, of radio frequency signal amplifiers.

Graph (E) more specifically illustrates the performance of a radio frequency signal amplifier of the type of the amplifiers 100 and 200 described in relation with FIGS. 1 and 2, but comprising no capacitive elements of the type of transistors T111, T112, T113, and T114 or of the type of capacitors C213 and C214. Graph (F) more specifically illustrates the performance of a radio frequency signal amplifier of the type of amplifiers 100 and 200 which use capacitive elements of the type of transistors T111, T112, T113, and T114 or of the type of capacitors C213 and C214. The comparison of graphs (E) and (F) enables to study the differences introduced by the use of these capacitive elements.

Further, graph (E) comprises: a curve 501 of variation of the gain as a function of the power of the output signal; and a curve 502 of variation of the amplifier current as a function of the power of the output signal.

Further, graph (F) comprises: a curve 511 of variation of the gain as a function of the power of the output signal; and a curve 512 of variation of the amplifier current as a function of the power of the output signal.

The comparison of graphs (E) and (F) indicates that the use of the capacitive elements enables to protect the transistors of the output differential pair by regulating the output power of the amplifier when the input signal exceeds a threshold value.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A radio frequency signal amplifier, comprising:
an input differential pair including a first transistor and a second transistor;
an output differential pair including a third transistor and a fourth transistor;
a first capacitive element formed by a bipolar transistor coupled between a control terminal of said first transistor and a conduction terminal of said second transistor;
a second capacitive element formed by a bipolar transistor coupled between a control terminal of said second transistor and a conduction terminal of said first transistor;
a third capacitive element formed by a bipolar transistor coupled between a control terminal of said third transistor and a conduction terminal of said fourth transistor; and
a fourth capacitive element formed by a bipolar transistor coupled between a control terminal of said fourth transistor and a conduction terminal of said third transistor.

2. The amplifier according to claim 1, further comprising at least one coil coupled between the input differential pair and the output differential pair.

3. The amplifier according to claim 1, wherein, for each of the first, second, third and fourth capacitive elements, the bipolar transistor is configured with a base terminal connected to one of its emitter or collector terminals.

4. The amplifier according to claim 1, wherein the first, second, third and fourth transistors are bipolar transistors.

5. The amplifier according to claim 4, wherein the bipolar transistor of the first capacitive element and said first transistor have same dimensions.

6. The amplifier according to claim 5, wherein the bipolar transistor of the third capacitive element and said third transistor have same dimensions.

7. The amplifier according to claim 1, further including an input terminal coupled to a first coil of a transformer, said transformer having a second coil having a first terminal coupled to a control terminal of the first transistor and a second terminal coupled to a control terminal of the second transistor.

8. The amplifier according to claim 7, wherein the first terminal of the second coil is coupled to the control terminal of the first transistor through a first capacitor, and wherein the second terminal of the second coil is coupled to the control terminal of the second transistor through a second capacitor.

9. The amplifier according to claim 1, further comprising: a third capacitor coupled between a control terminal of the third transistor and a reference node; and a fourth capacitor coupled between a control terminal of the fourth transistor and the reference node.

10. The amplifier according to claim 1, further comprising:
a first coil coupled between a further conduction terminal of the third transistor and a supply node;
a second coil coupled between a further conduction terminal of the fourth transistor and the supply node; and
a third coil coupled between an output node of the amplifier and a reference node;
wherein the third coil is magnetically coupled to the first and second coils.

11. The amplifier according to claim 10, wherein the third coil is coupled to the reference node through a capacitor.

12. The amplifier according to claim 1, further comprising:
a fifth coil coupled between a further terminal of the first transistor and a reference node; and
a sixth coil coupled between a further terminal of the second transistor and the reference node.

13. A radio frequency signal amplifier, comprising:
an input differential pair including a first transistor and a second transistor;
an output differential pair including a third transistor and a fourth transistor;
a first capacitive element formed by a MOSFET transistor coupled between a control terminal of said first transistor and a conduction terminal of said second transistor;
a second capacitive element formed by a MOSFET transistor coupled between a control terminal of said second transistor and a conduction terminal of said first transistor;
a third capacitive element formed by a MOSFET transistor coupled between a control terminal of said third transistor and a conduction terminal of said fourth transistor; and
a fourth capacitive element formed by a MOSFET transistor coupled between a control terminal of said fourth transistor and a conduction terminal of said third transistor.

14. The amplifier according to claim 13, further comprising at least one coil coupled between the input differential pair and the output differential pair.

15. The amplifier according to claim 13, further including an input terminal coupled to a first coil of a transformer, said transformer having a second coil having a first terminal coupled to a control terminal of the first transistor and a second terminal coupled to a control terminal of the second transistor.

16. The amplifier according to claim 15, wherein the first terminal of the second coil is coupled to the control terminal of the first transistor through a first capacitor, and wherein the second terminal of the second coil is coupled to the control terminal of the second transistor through a second capacitor.

17. The amplifier according to claim 13, further comprising: a third capacitor coupled between a control terminal of the third transistor and a reference node; and a fourth capacitor coupled between a control terminal of the fourth transistor and the reference node.

18. The amplifier according to claim 13, further comprising:
a first coil coupled between a further conduction terminal of the third transistor and a supply node;
a second coil coupled between a further conduction terminal of the fourth transistor and the supply node; and
a third coil coupled between an output node of the amplifier and a reference node;
wherein the third coil is magnetically coupled to the first and second coils.

19. The amplifier according to claim 18, wherein the third coil is coupled to the reference node through a capacitor.

20. The amplifier according to claim 13, further comprising:
a fifth coil coupled between a further terminal of the first transistor and a reference node; and
a sixth coil coupled between a further terminal of the second transistor and the reference node.
